(19) United States
(12) Patent Application Publication
(10) Pub. No.: US 2012/0088356 A1
(43) Pub. Date: Apr. 12, 2012

(54) INTEGRATED PLATFORM FOR IN-SITU DOPING AND ACTIVATION OF SUBSTRATES

(75) Inventors: KARTIK SANTHANAM, Milpitas, CA (US); MARTIN A. HILKENE, Gilroy, CA (US); MATTHEW D. SCOTNEY-CASTLE, Morgan Hill, CA (US); PETER I. PORSHNEV, Poway, CA (US); SWAMINATHAN SRINIVASAN, Pleasanton, CA (US); SUNDAR RAMAMURTHY, Fremont, CA (US)

(73) Assignee: APPLIED MATERIALS, INC., Santa Clara, CA (US)

(21) Appl. No.: 13/227,034

(22) Filed: Sep. 7, 2011

Related U.S. Application Data
(60) Provisional application No. 61/382,700, filed on Sep. 14, 2010.

(51) Int. Cl. H01L 21/265

(52) U.S. Cl. 438/530; 250/492.21; 257/E21.334

(57) ABSTRACT

An integrated platform for processing substrates, comprising: a vacuum substrate transfer chamber; a doping chamber coupled to the vacuum substrate transfer chamber, the doping chamber configured to implant or deposit dopant elements in or on a surface of a substrate; a dopant activation chamber coupled to the vacuum substrate transfer chamber, the dopant activation chamber configured to anneal the substrate and activate the dopant elements; and a controller configured to control the integrated platform, the controller comprising a computer readable media having instructions stored thereon that, when executed by the controller, causes the integrated platform to perform a method, the method comprising: doping a substrate with one or more dopant elements in the doping chamber; transferring the substrate under vacuum to the dopant activation chamber; and annealing the substrate in the dopant activation chamber to activate the dopant elements.

### CROSS-REFERENCE TO RELATED APPLICATIONS

This application claims benefit of U.S. provisional patent application Ser. No. 61/382,700, filed Sep. 14, 2010, which is herein incorporated by reference.

### FIELD

Embodiments of the present invention generally relate to substrate processing.

### BACKGROUND

Beam-line ion implantation is a traditional method to implant dopants in a semiconductor substrate. Beam-line ion implantation is a high energy implantation technique where ions penetrate deeply into a substrate, such as a semiconductor wafer or other workpiece. Plasma doping is an alternative to beam-line ion implantation that is sometimes used to implant dopants in a semiconductor substrate.

The inventors have provided herein improved methods and apparatus for in-situ doping and activation of semiconductor substrates.

### SUMMARY

Methods and apparatus for in-situ doping and activation of substrates have been provided herein. In some embodiments, an integrated platform for processing substrates may include: a vacuum substrate transfer chamber; a doping chamber coupled to the vacuum substrate transfer chamber, the doping chamber configured to implant or deposit dopant elements in or on a surface of a substrate; a dopant activation chamber coupled to the vacuum substrate transfer chamber, the dopant activation chamber configured to anneal the substrate and activate the dopant elements; and a controller configured to control the integrated platform to perform doping processes in the doping chamber and dopant activation processes in the dopant activation chamber and to transfer the substrate from the doping chamber to the dopant activation chamber using the vacuum substrate transfer chamber, the controller comprising a computer readable media having instructions stored thereon that, when executed by the controller, causes the integrated platform to perform a method, the method comprising: doping a substrate with one or more dopant elements in the doping chamber; transferring the substrate under vacuum to the dopant activation chamber; and annealing the substrate in the dopant activation chamber to activate the dopant elements.

In some embodiments, a method of processing a substrate may include: doping a substrate in a doping chamber with one or more dopant elements; transferring the substrate under vacuum from the doping chamber to a dopant activation chamber; and annealing the substrate to activate the dopant elements.

In some embodiments, a computer readable medium may be provided having instructions stored thereon that, when executed, cause an integrated platform to perform a method that may include: doping a substrate in a doping chamber with one or more dopant elements; transferring the substrate under vacuum from the doping chamber to a dopant activation chamber; and annealing the substrate to activate the dopant elements.

Other and further embodiments of the present invention are described below.

### BRIEF DESCRIPTION OF THE DRAWINGS

Embodiments of the present invention, briefly summarized above and discussed in greater detail below, can be understood by reference to the illustrative embodiments of the invention depicted in the appended drawings. It is to be noted, however, that the appended drawings illustrate only typical embodiments of this invention and are therefore not to be considered limiting of its scope, for the invention may admit to other equally effective embodiments.

FIG. 1 is a flow chart of a method for in-situ doping and activation of semiconductor substrates in accordance with some embodiments of the present invention.

FIG. 2 is a schematic diagram of an integrated platform for in-situ doping and activation of semiconductor substrates in accordance with some embodiments of the present invention.

FIG. 3 is a schematic diagram of an exemplary integrated platform for in-situ doping and activation of semiconductor substrates in accordance with some embodiments of the present invention.

To facilitate understanding, identical reference numerals have been used, where possible, to designate identical elements that are common to the figures. The figures are not drawn to scale and may be simplified for clarity. It is contemplated that elements and features of one embodiment may be beneficially incorporated in other embodiments without further recitation.

### DETAILED DESCRIPTION

Embodiments of the present invention provide improved methods and apparatus for in-situ doping and activation of substrates. Exemplary, but non-limiting, examples of applications of embodiments of the present invention include logic, DRAM, Flash, and FINFET structures and devices. Exemplary, but non-limiting, examples of target areas for doping may include polysilicon, ultra shallow junction (USJ), source drain regions, and silicon deep trench regions.

The inventors have observed that plasma doping technology is an attractive alternative to traditional beam-line ion implantation due to simplicity and high productivity. However, the inventors have observed that plasma doped substrates tend to have a very high surface concentration of dopants. As a result, the inventors believe that the dopants may be lost in post doping processing, for example, while exposed to high temperatures for extended times. The dopant loss may depend on many factors, including delay time between doping and subsequent processes, such as an anneal process, anneal temperature, and ambient atmosphere. In addition, the inventors believe that an arsenic (As) or phosphorus (P) containing surface film is a safety hazard due to the high toxicity of these elements combined with the dopant loss problem discussed above. For example, arsenic implanted substrates, exposed to atmosphere, will out-gas and release arsine (AsH₃), which has a threshold limit value (TLV) of less than 50 parts per billion (ppb).

The inventors have further observed that the risk of out-gassing is removed (or greatly limited) after an anneal process is performed on doped substrates, thus making arsenic and phosphorus doped substrates safer to handle. In addition, the inventors have observed that the annealed substrates do not lose dopant when exposed to atmosphere.

Thus, the inventors have provided methods and apparatus that may facilitate performing an anneal process as fast as possible after a plasma doping process. In addition, the substrate transfer may be done inside a vacuum chamber such that the tool operator is not exposed to out-gassing. Although discussed primarily in term of doping and activation, embodiments of the apparatus and methods disclosed herein may be used for applications such as dopant activation control, diffusion profile engineering/control, solid-state reaction control, microstructure/morphology modification, and the like.

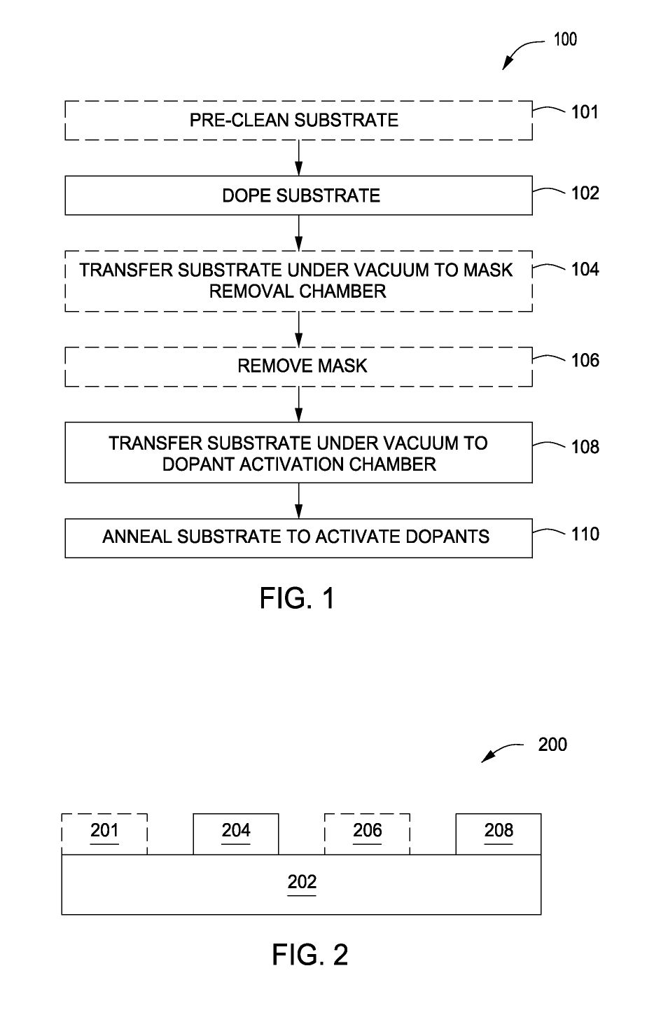

In some embodiments of the invention, a complete process integration solution is provided for doping, optional mask or photoresist strip, and dopant activation. For example, FIG. 1 depicts a flow chart of a method 100 for in-situ doping and activation of semiconductor substrates in accordance with some embodiments of the present invention.

The method 100 generally begins at 101 where the substrate may be optionally pre-cleaned prior to the doping process (described below). By pre-cleaning the substrate prior to the doping process contaminants from previously performed processes may be removed. In some embodiments, the pre-cleaning process may function to remove an oxide layer, for example a native oxide layer, from the surface of the substrate.

The substrate may comprise any suitable material used in the fabrication of semiconductor devices. For example, in some embodiments, the substrate may comprise a semiconducting material and/or combinations of semiconducting materials and non-semiconductive materials for forming semiconductor structures and/or devices. For example, the substrate may comprise one or more silicon-containing materials such as crystalline silicon (e.g., Si<100> or Si<111>), silicon oxide, strained silicon, polysilicon, silicon wafers, glass, sapphire, or the like. The substrate may further have any desired geometry, such as a 200 or 300 mm wafer, square or rectangular panels, or the like. In some embodiments, the substrate may be undoped, or may contain undoped regions that are to be subsequently doped. As used herein, undoped means not having an n-type or p-type dopant contained therein. Alternatively, in some embodiments, the substrate may be doped, with further doping of the substrate or portions thereof to be performed.

The pre-cleaning process may be any process suitable to facilitate removal of any material from the substrate surfaces, for example, such as the contaminants or oxide layer discussed above. For example, in embodiments where a native oxide layer is to be removed from the substrate the pre-cleaning process may comprise, for example, a SICONI™ Pre-clean process performed in a suitable chamber, such as a process chamber that utilizes SICONI™ technology available from Applied Materials, Inc., of Santa Clara, Calif.

In such embodiments, the substrate may be exposed to a fluorine containing precursor and a hydrogen containing precursor in a two part dry chemical clean process. In some embodiments, the fluorine containing precursor may comprise nitrogen trifluoride (NF₃), hydrogen fluoride (HF), diatomic fluorine (F₂), monatomic fluorine (F) and fluorine-substituted hydrocarbons, combinations thereof, or the like. In some embodiments, the hydrogen containing precursors may comprise atomic hydrogen (H), diatomic hydrogen (H2), ammonia (NH3), hydrocarbons, incompletely halogen-substituted hydrocarbons, combinations thereof, or the like.

In some embodiments, the first part in the two part process may comprise using a remote plasma source to generate an etchant species (e.g., ammonium fluoride (NHF₄)) from the fluorine containing precursor (e.g., nitrogen trifluoride (NF₃)) and the hydrogen containing precursor (e.g., ammonia (NH₃)). By using a remote plasma source, damage to the substrate may be minimized. The etchant species are then introduced into the pre-clean chamber and condensed into a solid by-product on the substrate surface through a reaction with native oxide layer. The second step may then comprise an in-situ anneal to decompose the by-product using convection and radiation heating. The by-product then sublimates and may be removed from the substrate surface via a flow of gas and pumped out of the pre-clean chamber.

Next at 102, the substrate is doped. The doping process may be performed in any suitable doping chamber, such as a plasma-assisted doping chamber. Examples of suitable doping chambers may include plasma immersion ion implantation process chambers, for example, the CONFORMA™ process chamber available from Applied Materials, Inc., of Santa Clara, Calif. Although specific process chambers may be provided herein to illustrate embodiments of the invention, it is contemplated that other suitable process chambers may also be used, including process chambers from other manufacturers.

The dopant may comprise any suitable element or elements typically used in semiconductor doping processes. Examples of suitable dopants include one or more of group III elements or group V elements, such as, in a non-limiting example, arsenic (As), boron (B), indium (In), phosphorous (P), antimony (Sb), or the like. Examples of n-type dopants may include at least one of phosphorus, arsenic, or the like. For example arsine (AsH₃) or phosphine (PH₃) are a typical dopant precursors used for n-type implant process targeting conformal FINFET (FIN Field Effect Transistors), conformal DRAM (Dynamic Random Access Memory) and conformal Flash doping applications. For p-type doping, boron-containing precursors, such as boron trifluoride (BF₃), diborane (B₂H₆), or the like, may be used. Examples of other dopants suitable for material modification of the substrate, or portions thereof, include germane (GeH₄), methane (CH₄), carbon dioxide (CO₂), carbon tetrafluoride (CF₄), silane (SiH₄), silicon tetrafluoride (SiF₄), nitrogen (N₂), and oxygen (0₂).

In some embodiments, doping can be performed in an implantation process, such as a plasma assisted implantation process. Alternatively or in combination, the doping process may also be performed by depositing a precursor on the target surface. Either process may be performed in the CONFORMA™ process chamber available from Applied Materials, Inc.

When doping the substrate, the entire surface of the substrate may be doped or if select regions of the substrate are to be doped, a patterned mask layer, such as a patterned photoresist layer, may be deposited atop the substrate to protect regions of the substrate that are not to be doped.

In embodiments where a mask layer is used to protect the substrate during the doping process, the mask layer may be removed prior to annealing the substrate. For example, in some embodiments the substrate may be transferred under vacuum to a mask removal chamber, where the mask layer may be removed, as shown at 104-106 in FIG. 1. In some embodiments, the mask layer may comprise a layer of photoresist. The mask layer may be stripped, for example, by exposure to a plasma comprising one or more of oxygen (O₂), nitrogen trifluoride (NF₃), carbon tetrafluoride (CF₄), hydrogen (H₂), or nitrogen (N₂) gas. Depending on any damage to the mask layer, plasma chemistry, and plasma density, the mask layer can be removed in a chamber similar to the doping chamber (e.g., a CONFORMA™ process chamber). For example, process parameters that may be adjusted to facilitate mask layer removal may include RF source power (e.g. RF power provided to plasma), gas flow, chamber pressure, and time. The mask removal chamber may be any chamber able to perform the optional mask removal process. Non-limiting examples of such suitable chambers include the aforementioned CONFORMA™ process chamber, or the Axiom process chamber, also available from Applied Materials Inc.

Next, at 108, the substrate may be transferred under vacuum to a dopant activation chamber, where at 110, the substrate may be annealed to activate the dopants implanted in or disposed on the substrate. For example, the substrate may be annealed by heating the substrate to a first temperature of between about 600 to about 1300 degrees Celsius. In some embodiments, the substrate may be held at the first temperature for a first period of time from about 1 second to few hours. The substrate may be annealed in an inert atmosphere. In some embodiments, the substrate may be annealed in a nitrogen (N₂) atmosphere. If the substrate does not have a patterned mask to protect areas for doping, the substrates can be directly transferred from the doping chamber after the doping process to the dopant activation chamber. The inventors have discovered that dopant loss and dielectric film build up (e.g., build up of a dielectric film, such as boron oxide, due to exposure to moisture) can be reduced by in-situ dopant activation (e.g., anneal) and by not exposing the substrate to the atmosphere. The dopant activation process may be a high temperature process such as an anneal, and may be performed in any suitable process chamber, such as the RTP RADIANCE® process chamber, also available from Applied Materials Inc.

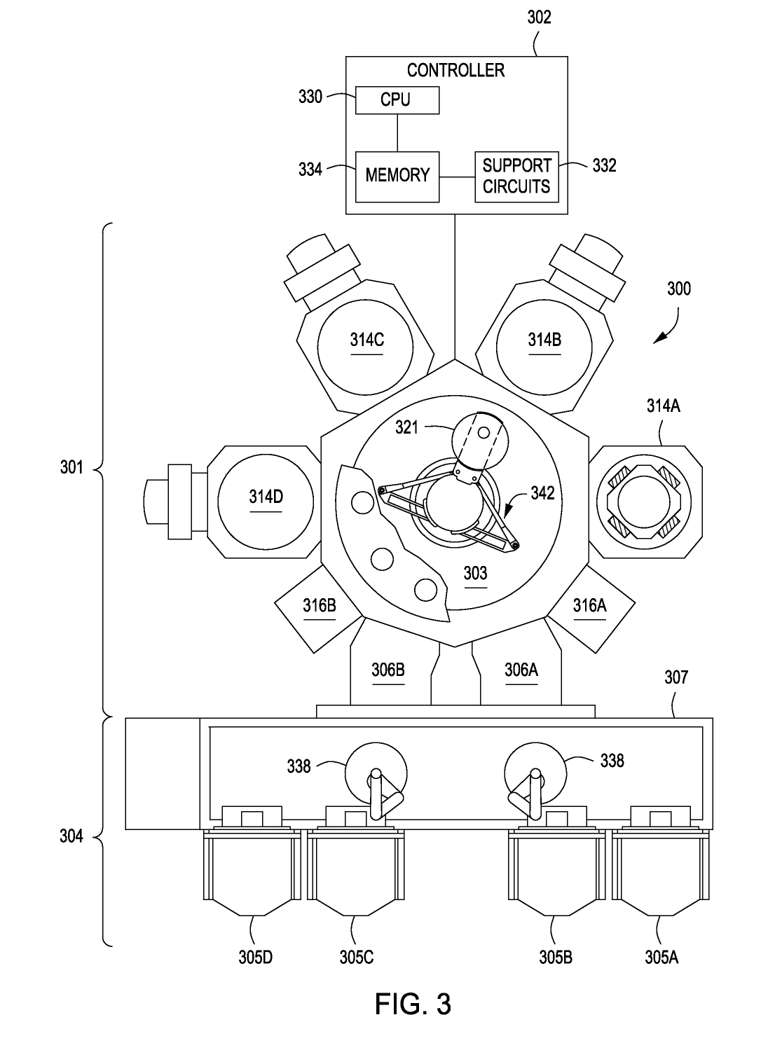

FIG. 2 is a schematic diagram of an integrated platform 200 for in-situ doping and activation of semiconductor substrates in accordance with some embodiments of the present invention. The integrated platform 200 shows a configuration suitable for performing embodiments of the method 100 discussed above. The integrated platform 200 may include a first process chamber 204 and a second process chamber 208 each coupled to a common transfer chamber 202. The transfer chamber 202 may contain a substrate transfer robot for transferring substrates to and from the various process chambers coupled thereto. The transfer chamber 202 may further comprise one or more openings (not shown) to facilitate delivering substrates to or removing substrates from the integrated platform 200. One or more load lock chambers (not shown) may further be coupled to the transfer chamber 202, for example, at the one or more openings, to facilitate exchanging the substrate between atmospheric conditions outside of integrated platform 200 and vacuum conditions within the integrated platform 200.

The first process chamber 204 may be configured to perform the doping process, for example, to implant and/or deposit one or more dopant elements in desired regions of a semiconductor substrate. The second process chamber 208 may be configured to perform the dopant activation process, for example, an annealing process. In some embodiments, one or more additional process chambers (a third process chamber 206 and a fourth process chamber 201 shown) may be provided to perform other processes, for example such as a mask removal when a patterned mask layer is provided or a pre-clean process, such as the pre-clean process described above.

In operation, the substrate may first be optionally pre-cleaned in the fourth process chamber 201. The substrate may then be doped (implant or deposited) in the first process chamber 204. In embodiments where a patterned mask layer is provided, the substrate may then be moved to the third process chamber 206 to have the mask layer removed. After removal of the patterned mask layer, the substrate may be moved to the second process chamber 208 to activate the dopants. Embodiments where no patterned mask layer is provided, the substrate may be moved directly into the second process chamber 208 from the first customer 204. All processes can be performed under vacuum in the integrated platform 200.

FIG. 3 depicts a schematic diagram of an exemplary integrated platform 300 (e.g., a cluster tool) in accordance with some embodiments of the present invention (such as the CENTURA® line of integrated processing systems, available from Applied Materials, Inc.). The particular embodiment of the integrated platform 300 is illustrative only and should not be used to limit the scope of the invention. It is contemplated that the integrated platform 300 may have other configurations with other semiconductor substrate processing systems and/or processing reactors.

In some embodiments, the integrated platform 300 includes a vacuum-tight processing platform 301, a factory interface 304, and a controller 302. The platform 301 comprises multiple processing chambers, such as 314A, 314B, 314C, and 314D operatively coupled to a vacuum substrate transfer chamber 303. The factory interface 304 is operatively coupled to the transfer chamber 303 by one or more load lock chambers (two load lock chambers, such as 306A and 306B shown in FIG. 3).

In some embodiments, the factory interface 304 comprises at least one docking station 307, at least one factory interface robot 338 to facilitate the transfer of the semiconductor substrates. The docking station 307 is configured to accept one or more front opening unified pod (FOUP). Four FOUPS, such as 305A, 305B, 305C, and 305D are shown in the embodiment of FIG. 3. The factory interface robot 338 is configured to transfer the substrates from the factory interface 304 to the processing platform 301 through the loadlock chambers, such as 306A and 306B. Each of the loadlock chambers 306A and 306B have a first port coupled to the factory interface 304 and a second port coupled to the transfer chamber 303. The load lock chamber 306A and 306B are coupled to a pressure control system (not shown) which pumps down and vents the chambers 306A and 306B to facilitate passing the substrates between the vacuum environment of the transfer chamber 303 and the substantially ambient (e.g., atmospheric) environment of the factory interface 304. The transfer chamber 303 has a transfer robot 342 disposed therein. The transfer robot 342 is capable of transferring substrates 321 between the load lock chamber 306A and 306B and the processing chambers 314A, 314B, 314C, and 314D.

In some embodiments, the processing chambers 314A, 314B, 314C, and 314D, are coupled to the transfer chamber 303. The processing chambers 314A, 314B, 314C, and 314D may be any type of processing chambers suitable to perform the above discussed processes (e.g., doping chambers, activation chambers, mask removal chambers, pre-clean chambers, or the like). Although only four processing chambers are shown, any number of processing chambers may be present to accommodate for the amount of processes being performed. For example, in some embodiments, the integrated platform 300 may comprise more or, in some embodiments, less than the four processing chambers 314A, 314B, 314C, and 314D shown.

For example, in some embodiments, the processing chambers 314A, 314B, 314C, and 314D may comprise two doping chambers and two dopant activation chambers, or in some embodiments, two doping chambers, one mask removal chamber, and one dopant activation chamber. Alternatively, or in combination, in some embodiments, a pre-clean chamber may be included in addition to, or instead of one of the processing chambers 314A, 314B, 314C, and 314D in the aforementioned examples.

Examples of chambers suitable for performing at least some of the embodiments of the invention have been discussed above. For example in some embodiments, the processing chambers 314A, 314B, 314C, 314D, may comprise two CONFORMA™ process chambers and two RTP RADIANCE® process chambers, or two CONFORMA™ process chambers, either another CONFORMA™ process chamber or an AXIOM process chamber, and one RTP RADIANCE® chamber. Alternatively, or in combination, in some embodiments, the processing chambers 314A, 314B, 314C, 314D may comprise a process chamber that utilizes SICONI™ technology to perform a SICONI™ Pre-clean process.

In some embodiments, one or more optional service chambers (shown as 316A and 316B) may be coupled to the transfer chamber 303. The service chambers 316A and 316B may be configured to perform other substrate processes, such as degassing, orientation, substrate metrology, cool down and the like.

The system controller 302 controls the operation of the platform 300 using a direct control of the process chambers 314A, 314B, 314C, and 314D or alternatively, by controlling the computers (or controllers) associated with the process chambers 314A, 314B, 314C, and 314D and the platform 300. In operation, the system controller 302 enables data collection and feedback from the respective chambers and systems to optimize performance of the platform 300. The system controller 302 generally includes a Central Processing Unit (CPU) 330, a memory 334, and a support circuit 332. The CPU 330 may be one of any form of a general purpose computer processor that can be used in an industrial setting. The support circuit 332 is conventionally coupled to the CPU 330 and may comprise a cache, clock circuits, input/output subsystems, power supplies, and the like. Embodiments of the method 100 discussed above may be stored in the memory 334 as a software routine. These software routines, when executed by the CPU 330, transform the system controller 302 into a specific purpose computer (controller) 302. The software routines may also be stored and/or executed by a second controller (not shown) that is located remotely from the platform 300.

Using the integrated platform 200, 300, the substrate advantageously remains in a vacuum environment during the transfer from the doping chamber to the dopant activation chamber (and the mask removal chamber, when used). For one illustrative chamber serial doping/activation sequence, the time delay from end of the doping process to the start of the activation process was less than 20 seconds.

Thus, improved methods and apparatus for in-situ doping and activation of semiconductor substrates have been provided. Embodiments of the present invention may advantageously reduce dopant loss. Embodiments of the present invention may also reduce exposure of the tool operator to out-gassing of toxic or potentially toxic compounds.

While the foregoing is directed to embodiments of the present invention, other and further embodiments of the invention may be devised without departing from the basic scope thereof.

1. An integrated platform for processing substrates, comprising:
a vacuum substrate transfer chamber;
a doping chamber coupled to the vacuum substrate transfer chamber, the doping chamber configured to implant or deposit dopant elements in or on a surface of a substrate;
a dopant activation chamber coupled to the vacuum substrate transfer chamber, the dopant activation chamber configured to anneal the substrate and activate the dopant elements; and
a controller configured to control the integrated platform to perform doping processes in the doping chamber and dopant activation processes in the dopant activation chamber and to transfer the substrate from the doping chamber to the dopant activation chamber using the vacuum substrate transfer chamber, the controller comprising a computer readable media having instructions stored thereon that, when executed by the controller, causes the integrated platform to perform a method, the method comprising:
doping a substrate with one or more dopant elements in the doping chamber;
transferring the substrate under vacuum to the dopant activation chamber; and
annealing the substrate in the dopant activation chamber to activate the dopant elements.

2. The integrated platform of claim 1, further comprising:
a mask removal chamber coupled to the vacuum substrate transfer chamber, the mask removal chamber configured to remove a mask layer deposited on the substrate.

3. The integrated platform of claim 2, wherein the controller is further configured to transfer the substrate from the doping chamber to the mask removal chamber and from the mask removal chamber to the dopant activation chamber using the vacuum substrate transfer chamber.

4. The integrated platform of claim 2, wherein the instructions of the computer readable media further cause the integrated platform to transfer the substrate under vacuum to the mask removal chamber to remove the patterned mask from the substrate after doping the substrate and prior to annealing the substrate.

5. The integrated platform of claim 1, further comprising:
a second doping chamber coupled to the vacuum substrate transfer chamber; and
a second dopant activation chamber coupled to the vacuum substrate transfer chamber.

6. The integrated platform of claim 1, further comprising:
a second doping chamber coupled to the vacuum substrate transfer chamber; and
a mask removal chamber coupled to the vacuum substrate transfer chamber, the mask removal chamber configured to remove a mask layer deposited on the substrate.

7. The integrated platform of claim 1, further comprising:
one or more loadlock chambers coupled to the vacuum substrate transfer chamber.

8. The integrated platform of claim 1, further comprising:
a pre-clean chamber coupled to the vacuum substrate transfer chamber to clean the substrate prior to implanting or depositing the dopant elements in or on the surface of the substrate.

9. The integrated platform of claim 8, wherein the instructions of the computer readable media further cause the integrated platform to transfer the substrate under vacuum to the pre-clean chamber to pre-clean the substrate to remove at least one of contaminants or an oxide layer from a surface of the substrate prior to doping the substrate and prior to annealing the substrate.

10. A method of processing a substrate, comprising:
doping a substrate in a doping chamber with one or more dopant elements;
transferring the substrate under vacuum from the doping chamber to a dopant activation chamber; and
annealing the substrate to activate the dopant elements.

11. The method of claim 10, wherein annealing the substrate comprises heating the substrate to a temperature of about 600 to about 1300 degrees Celsius.

12. The method of claim 10, wherein the substrate further comprises a patterned mask disposed atop the substrate to define regions where the substrate is to be doped, and further comprising:
transferring the substrate under vacuum to a mask removal chamber after doping the substrate and prior to annealing the substrate;
removing the patterned mask from the substrate; and
after removing the patterned mask from the substrate, transferring the substrate under vacuum from the mask removal chamber to the dopant activation chamber.

13. The method of claim 12, wherein removing the patterned mask comprises exposing the substrate to a plasma formed from one of oxygen (O₂), nitrogen trifluoride (NF₃), carbon tetrafluoride (CF₄), hydrogen (H₂), or nitrogen (N₂) gas.

14. The method of claim 12, further comprising:
transferring the substrate under vacuum to a pre-clean chamber prior to doping the substrate and prior to annealing the substrate; and
pre-cleaning the substrate to remove at least one of contaminants or an oxide layer from a surface of the substrate.

15. The method of claim 14, wherein pre-cleaning the substrate comprises:
exposing the substrate to a plasma formed from a fluorine containing precursor and a hydrogen containing precursor to form a solid byproduct atop a surface of the substrate; and
flowing a gas across the surface of the substrate to remove the solid byproduct.

16. A computer readable medium having instructions stored thereon that, when executed, cause the integrated platform to perform a method, the method comprising:
doping a substrate in a doping chamber with one or more dopant elements;
transferring the substrate under vacuum from the doping chamber to a dopant activation chamber; and
annealing the substrate to activate the dopant elements.

17. The computer readable medium of claim 16, wherein the method further comprises:
transferring the substrate under vacuum from the doping chamber to a mask removal chamber after doping the substrate and prior to annealing the substrate;
removing a patterned mask from the substrate, wherein the patterned mask is disposed atop the substrate to define regions where the substrate is to be doped; and
then transferring the substrate under vacuum from the mask removal chamber to the dopant activation chamber.

18. The computer readable medium of claim 17, wherein removing the patterned mask from the substrate comprises exposing the substrate to a plasma formed from one of oxygen (O₂), nitrogen trifluoride (NF₃), carbon tetrafluoride (CF₄), hydrogen (H₂), or nitrogen (N₂) gas.

19. The computer readable medium of claim 16, wherein the method further comprises:
transferring the substrate under vacuum to a pre-clean chamber prior to doping the substrate and prior to annealing the substrate; and
pre-cleaning the substrate to remove at least one of contaminants or an oxide layer from a surface of the substrate.

20. The computer readable medium of claim 19, wherein pre-cleaning the substrate comprises:
exposing the substrate to a plasma formed from a fluorine containing precursor and a hydrogen containing precursor to form a solid byproduct atop a surface of the substrate; and
flowing a gas across the surface of the substrate to remove the solid byproduct.
